(19) United States
(12) Patent Application Publication
(10) Pub. No.: US 2006/0225775 A1
(43) Pub. Date: Oct. 12, 2006

(54) Solar cell

(76) Inventor: Shunichi Ishihara, TOKYO (JP)

Correspondence Address: FITZPATRICK CELLA HARPER & SCINTO, 30 ROCKEFELLER PLAZA, NEW YORK, NY, 10112, US

(21) Appl. No.: 10/549,900

(22) PCT Filed: Mar. 24, 2004
(86) PCT No.: PCT/JP04/04072

§ 371 Date: Sep. 20, 2005

(30) Foreign Application Priority Data
Mar. 26, 2003 (JP) 2003-084537

(51) Int. Cl. H01L 31/00; H02N 6/00; H01L 31/042

(52) U.S. Cl. 136/244; 136/256

(57) ABSTRACT

Provided is a solar cell having a silicon substrate for a solar cell, the substrate being formed by allowing a high-purity polycrystalline silicon layer to grow on a surface of a base that is sliced from a polycrystalline silicon ingot which is obtained by melting metal-grade silicon and solidifying the silicon in one direction, wherein a layer having a non-doped amorphous silicon phase and a microcrystalline silicon phase mixed together is stacked on the high-purity polycrystalline silicon layer.

### TECHNICAL FIELD

The present invention relates to a polycrystalline silicon solar cell that can be produced at a low cost and that hardly suffers from a limit of a silicon resource in production thereof.

### BACKGROUND ART

A solar cell has been widely employed with a growing awareness of the environments. In the production of a general solar cell, a single-crystalline or polycrystalline silicon substrate has been mainly used. The single-crystalline silicon for the solar cell is basically formed by pulling using the Czochralski method that is also used in the production of silicon for semiconductor. On the other hand, the polycrystalline silicon substrate can be produced by melting and solidifying silicon in a crucible with higher throughput than the single-crystalline silicon. However, in many cases, a silicon wafer which has been out of the standard in the IC industry or the like or a remaining pulled silicon is recycled as a raw material for polycrystalline silicon, as a result of which the amount of supply of the raw material is limited, and the cost cannot be reduced so much.

Under the above circumstances, an attempt has been made to refine polycrystalline silicon that has been produced by using inexpensive unrefined silicon (metal-grade silicon) which has been merely reduced directly from silica, not through a silicon refining process for semiconductor such as the Siemens method. For example, K. Hanazawa, M. Abe, H. Baba, N. Nakamura, N. Yuge, Y. Sakaguchi, Y. Kato, S. Hiwasa and M. Obashi have proposed a technique in which a silicon raw material for the solar cell is obtained by removing a large amount of P and B contained in the metal-grade silicon by using an EB gun or a plasma torch (12^{th} PVSEC June 1045 2001 proceeding p265-268). However, even in this method, because it is particularly difficult to remove B, resulting in a necessity for a two-step process, the reduction of cost cannot be realized as expected.

Also, an attempt has been made to directly grow the polycrystalline silicon on a base made of a material other than silicon. However, the growth has to be normally conducted at a high temperature ranging from 1000 to 1500° C., and it is difficult to use metal or glass as the base from the viewpoints of matching of the heat resistance or the coefficient of thermal expansion with silicon. As a result, an attempt has been made to use glassy carbon or ceramics. However, there is a tendency that a polycrystalline silicon film that has grown on the base of that type is small in crystal grains, and the flatness of the surface of the polycrystalline silicon film becomes deteriorated, and therefore the base of that type has not been put to practical use. Moreover, glassy carbon or ceramics is not at all an inexpensive material to be used for the solar cell.

Under the above circumstances, there has been proposed a method in which the solar cell is formed by using a substrate formed by allowing a silicon layer having high purity and a given thickness to grow on the base made from inexpensive metal-grade silicon. For example, Haruo ITO, Tadashi SAITOH, Noboru NAKAMURA, Sunao MATSUBARA, Terunori WARABISAKO, and Takashi TOKUYAMA have fabricated a solar cell by way of trial, by growing silicon polycrystal on the base made of metal-grade silicon through the CVD method by using SiH₂Cl₂ (J. Crys. Growth 45(1978) 446-453). Also, NOGUCHI, SANO and IWATA have also proposed a solar cell defined in claims 1 to 3 in which polycrystalline silicon that is high in purity to the semiconductor grade is allowed to grow on a base made of solar cell metal-grade silicon (Japanese Patent Application Laid-Open No. H5-36611). According to those methods, the base is made of silicon although it is low in purity, and there arises no problem on the unmatching of the heat resistance and the coefficient of thermal expansion. Also, because the grown polycrystalline silicon film has the crystallinity similar to that of the base, a higher-quality crystallinity can grow on the metal-grade base compared with the case of the base made of glassy carbon or ceramics. However, in the method of growing silicon from a gas phase such as the CVD method, the number of films throwable per one batch is limited, and there arises such a problem that a film is peeled off from an inner wall of the device during growing. In addition, in the case where polycrystalline silicon is grown on a base made of silicon having a low purity such as the metal-grade silicon, impurities such as metal, B or P contained in the base are liable to be contained in the high-purity silicon layer again after the impurities leave in gas phase once. In that case, even if the purity of a silicon gas to be used as a raw material is increased, there is a high tendency that the grown silicon layer is contaminated with the metal, or reduced in resistance to the degree that the resistance is improper for the production of the solar cell.

T. H. Wang, T. F. Ciszek, C. R. Schwertfeger, H. M. Mountinho, R. Matson have proposed a method in which liquid-phase growth is utilized for the growth of a high-purity silicon layer on a metal-grade silicon (Solar Cell Materials and Solar Cells 41/42 (1996) 19-30). Also, Nishida has proposed that a high-purity silicon layer is allowed to grow on a base made from metal-grade silicon by the liquid-phase method so as to be used for the solar cell (Japanese Patent Application Laid-Open No. H10-98205). In the proposal by Nishida, there are disclosed various novel methods of the base formation as effective means for reducing the costs of the solar cell production.

The liquid-phase growth method enables the easy growth of a thick silicon layer, reduces a rate of wasting a silicon raw material, and therefore is highly suited to the production of the solar cell. Also, when the degree of supersaturation of melt is managed, an influence of the impurities of the base on the high-purity silicon layer becomes lower than that in the case of the growth from the gas-phase, thereby making it possible to obtain the polycrystalline silicon layer of high grade with relatively ease. Therefore, the liquid-phase epitaxy method is suitable for the formation of the substrate with a base made of the metal-grade silicon.

The above-mentioned solar cell using the substrate formed by allowing the high-purity polycrystalline silicon to grow on the metal-grade silicon base through the liquid-phase method is promising for the future. However, there is still a problem for the future at the present stage where the research and development have started, in particular, a problem on the method of producing the high-efficiency solar cell.

In general, an emitter layer having a conductivity type opposite to that of the polycrystalline silicon layer is formed on the substrate. However, as a result of the experiment, it is found that when a high-resistant silicon film containing H such as amorphous Si or microcrystalline Si is deposited in the thickness of 1 nm to 10 nm on the polycrystalline silicon layer to form a buffer layer, a solar cell characteristic, in particular, an open circuit voltage, remarkably increases. This has already been disclosed in Japanese Patent Application Laid-Open Nos. H5-36611 and H5-48128. However, in the disclosure of those applications, a non-doped amorphous Si layer is used as a buffer layer, and a doped amorphous Si layer is used as an emitter layer. For that reason, the conductivity of the emitter layer is not sufficiently high, and therefore an ITO layer is formed on the emitter layer as an electrically conductive antireflection film. Because the ITO film is electrically conductive, it absorbs light and a generated current is lost. In the inventors' experiment, a current loss of about 5% was found when an ITO film having 100 Ω in sheet resistance was used.

In the case where the doped amorphous silicon layer is used as the emitter layer, the use of an insulating film that is high in transparency instead of an ITO film makes it impossible to sufficiently increase the conductivity and induces a deterioration of a fill factor (FF). Also, in order to obtain the required conductivity, the doped amorphous silicon layer has to have a thickness in the order of mm, and when the doped amorphous silicon layer is made so thick, light hardly reaches the polycrystalline silicon layer of the active layer.

For that reason, it is necessary to form a doped crystalline silicon film as the emitter layer, and the crystalline silicon film is required to be formed on a non-doped buffer layer. In general, it is difficult to allow a crystalline silicon film to grow directly on an amorphous silicon film, and the amorphous silicon layer having a certain constant thickness exists as an incubation layer. The light absorption on the amorphous silicon layer causes a reduction of the light that reaches the active layer, whereby the generated current reduces.

As described above, many problems still remain in the fabrication of a substrate for a solar cell, having a base of low-purity silicon such as metal-grade silicon, and in the fabrication of the solar cell using such a substrate.

### DISCLOSURE OF THE INVENTION

An object of the present invention is to provide a highly-efficient solar cell using a substrate for a solar cell, wherein the substrate is mainly made of low-purity silicon as a raw material and can greatly reduce the costs as compared with a conventional polycrystalline silicon substrate.

The present invention has been accomplished in view of the above circumstance, and in a preferred example of the present invention, a buffer layer consisting of a part having a crystallinity similar to that of a high-purity polycrystalline silicon layer underneath and the rest part being an amorphous silicon layer, is formed on a silicon substrate for a solar cell, obtained by growing a high-purity polycrystalline silicon layer on a base formed by slicing an ingot prepared by using low-purity silicon represented by metal-grade silicon, a polycrystalline silicon film is grown on the buffer layer with using the crystal portion of the buffer layer as a seed to form an emitter layer of the polycrystalline silicon film, and an SiN film is formed on the emitter layer as an antireflection film.

In this example, however, the antireflection film is not essential. Also, the use of the silicon substrate for a solar cell obtained by growing the high-purity polycrystalline silicon layer on the base formed by slicing the ingot prepared by using the low-purity silicon represented by metal-grade silicon is advantageous from the viewpoint of the costs, but the effect of the present invention is obtained by other modes.

Consequently, the most basic mode of the present invention is represented by a solar cell having a crystalline silicon substrate or a crystalline silicon layer, a layer in which an amorphous silicon phase and a microcrystalline silicon phase are mixed together, and a polycrystalline silicon layer that has grown with the microcrystalline silicon phase as a seed, which are stacked in the mentioned order. In this example, crystalline silicon may be a crystalline silicon wafer or a crystalline silicon layer formed on a substrate. In the present specification, crystal means single crystal or polycrystal. It is practical to use a polycrystalline silicon wafer or a polycrystalline silicon layer formed on a substrate.

Also, it is possible to preferably use a nondoped layer as the layer in which the amorphous silicon phase and the microcrystalline silicon phase are mixed together.

From the viewpoint of cost reduction, there is provided a solar cell using a solar cell silicon substrate for a solar cell, the substrate being formed by growing a high-purity polycrystalline silicon layer on the surface of a base formed by slicing an polycrystalline silicon ingot obtained by melting metal-grade silicon and solidifying the metal-grade silicon in one direction, wherein a layer in which a nondoped amorphous silicon phase and a microcrystalline silicon phase are mixed together is stacked on the high-purity polycrystalline silicon layer.

It is needless to say that an intermediate mode between the above-mentioned basic mode and the mode provided from the viewpoint of the cost reduction is provided by the present invention.

### BRIEF DESCRIPTION OF THE DRAWINGS

FIG. 1 is a cross-sectional view showing a polycrystalline silicon solar cell in accordance with the present invention;

FIG. 2 a cross-sectional view showing another polycrystalline silicon solar cell in accordance with the present invention;

FIG. 3 is a diagram showing the structure of an apparatus for producing a polycrystalline silicon ingot in accordance with a preferred embodiment of the present invention;

FIG. 4 is a diagram showing the structure of a liquid-phase growth apparatus in accordance with the preferred embodiment of the present invention;

FIG. 5 is a diagram showing the structure of another liquid-phase growth apparatus in accordance with the preferred embodiment of the present invention; and

FIG. 6 is a diagram showing the structure of a plasma film formation apparatus in accordance with the preferred embodiment of the present invention.

### BEST MODE FOR CARRYING OUT THE INVENTION

Hereinafter, a description will be given in more detail of preferred embodiments of the present invention with reference to the accompanying drawings.

(Silicon as a Raw Material)

A silicon raw material that is most inexpensive and abundantly supplied is metal-grade silicon obtained by directly reducing silica. Norway, Brazil, China and so on are major producing countries. In general, the purity is nominally 97% or more, but the kind and density of impurities actually contained depend on silica of the raw material. A typical example is shown in Table 1.

TABLE 1

| Impurities | Density | |
|---|---|---|
| Fe | 1000 | ppmw |
| Al | 800 | ppmw |
| Cu | 15 | ppmw |
| Cr | 10 | ppmw |
| B | 10 | ppmw |
| P | 50 | ppmw |

Main impurities include a heavy metal such as Fe, Cr or Cu. Because those impurities exhibit a deep level in silicon and becomes the center of recombination, the solar cell characteristic is remarkably deteriorated. Moreover, since the heavy metal is liable to diffuse, contamination is liable to be widely spread in a high-purity silicon layer growing step and a solar cell fabricating step when the heave metal is contained in the material of the base with a high density. In addition, the metal impurities cohere into micro grains, as a result of which the solar cell may be shunted.

Also, impurities that become dopant such as B, Al or P are contained in the silicon raw material with a high density. The resistivity and conductivity type of the ingot are determined in accordance with the density of the dopant and the relative amount of a p-type dopand and an n-type dopant. The ingot may be of the p-type or n-type.

Also, even in the semiconductor-class or solar cell class silicon raw material which is low in the density of the impurities other than Al, B and P, when the resistivity becomes lower than a given limit (substantially 0.1 Ω cm or less), even if the solar cell is fabricated as it is, the obtained solar cell is low in the efficiency and is not put into practical use. Because the raw material of this type contains the dopant impurities such as Al, B or P to the degree higher than a practical use level, and cannot be used for manufacturing the device, the raw material can be acquired remarkably inexpensively as compared with the normal high-purity silicon, thereby being capable of effectively using such a silicon raw material as a low-purity silicon raw material of the present invention.

Even when the high-purity silicon is used, it falls within the scope of the present invention.

(Description of a Process for Producing a Substrate for Solar Cell)

(Formation and Slice of Ingot)

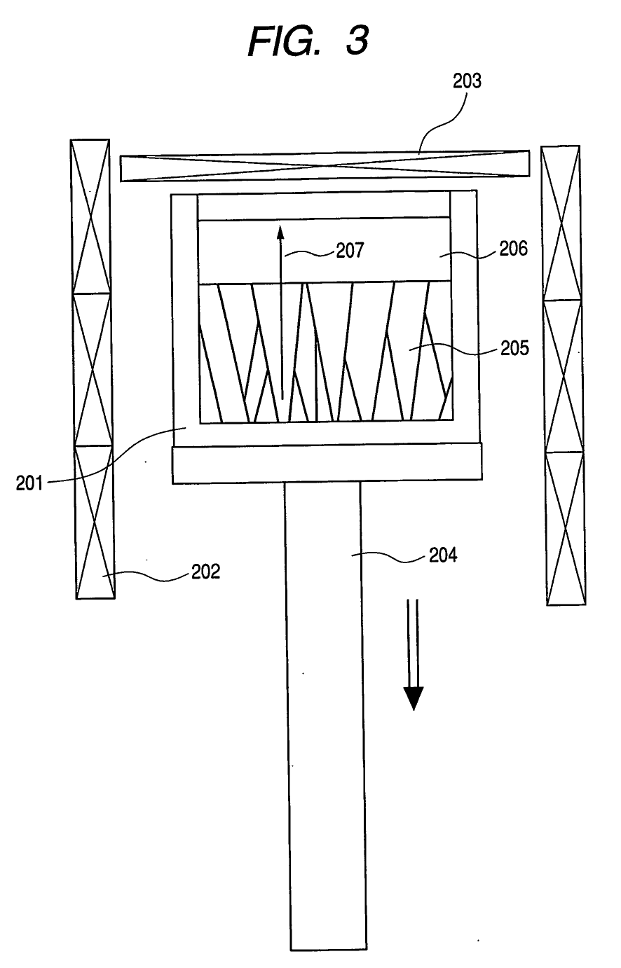

A base made of polycrystalline silicon is formed by melting and solidifying raw material silicon filled in a crucible and then slicing the obtained ingot of polycrystalline silicon in a given thickness by means of a wire saw. A preferred ingot solidifying apparatus in accordance with an embodiment of the present invention is shown in FIG. 3. It is desirable that the solidification of the raw material silicon melted in a crucible 201 gradually advances toward the upper surface of the crucible from the bottom of the crucible 201 (along a direction 207) while keeping the plane of an interface between a solidified portion 205 and a melted portion 206. To achieve this, the temperature of three cylindrical heaters 202 disposed at side surfaces of the crucible 201 is sloped from the upper portion of the crucible 201 toward the lower portion thereof, and a support 204 of the crucible 201 is slowly moved downward so that cooling advances. The heaters 203 is used to form the vertical temperature gradient, and crystal grains grow while extending from the bottom of the crucible 201 toward the upper surface of the crucible. The solidifying method of this type is called “unidirectional solidification”, and the heavy metal impurities are extruded from the solidified portion 205 by a segregation effect toward a melted solution 206 to result in decrease of the impurity density of the solidified polycrystal, and the impurities are condensed to the finally remaining melted solution. When the unidirectional solidification is appropriately conducted, the density of the heavy metal impurities in polycrystal can be reduced to 1/100 or less of the raw material silicon. Nevertheless, since the recombination of carriers generated due to an incident light increases to deteriorate the characteristics, the polycrystalline silicon cannot be used for manufacturing the solar cell. Also, B and P are extremely low in segregation effect, and the density of the impurities cannot be lowered through the unidirectional solidification. The above-mentioned method proposed by Haruo ITO, et al., aims at the removal of B and P which cannot be removed by the unidirectional solidification as easy as possible. However, two more steps must be needed as compared with those of the unidirectional solidification, as a result of which the costs are greatly increased.

In the present invention, the heavy metal is removed by the unidirectional solidification as much as possible, but refinement other than the unidirectional solidification is not conducted. Therefore, a satisfactory characteristics cannot be expected even if the formed polycrystalline silicon is used as the solar cell as it is. Also, in general, the resistivity largely fluctuates due to the density of B, Al or P, and when the polycrystalline silicon is sliced to form a base, even if a high-purity silicon layer is formed on the base, the solar cell characteristics are adversely affected. In order to form an ingot of p-type as a conductivity type and the resistivity of a given value (300 mΩ or less) by using the raw material silicon of this type, a given amount of B or Al may be added to the raw material silicon in accordance with the source or grade of the raw material metal-grade silicon. The amount of B or Al to be added has an upper limit and is limited to such a degree that the crystallinity of Si is not deteriorated, in particular, the size of the crystal grain is not remarkably decreased. For example, the amount of B is 2×10¹⁸ to 5×10¹⁹ cm⁻³, preferably 2×10¹⁸ to 4×10¹⁹ cm⁻³, and the amount of Al is 1×10¹⁹ to 1×10²¹ cm⁻³, preferably 1×10¹⁹ to 5×10²⁰ cm⁻³. The reason why the added amount of Al is larger than that of B is that Al is liable to be separated in the unidirectional solidification as compared with B. The base that is thus formed from the ingot has a junction with the polycrystalline silicon that is allowed to grow on the base, to thereby contribute to the solar cell characteristics, in particular, an improvement in an open circuit voltage as will be described later. Moreover, even when this method is implemented, an increase in the production costs is small unlike to the refinement.

The formed ingot is sliced into a flat plate having a thickness of 200 to 350 μm by a cutter of an inner peripheral blade type or a wire saw. The use of the wire saw that is high in the productivity is preferable for use in the solar cell. Because the ingot formed in accordance with the present invention is formed through the unidirectional solidification method, the crystal grains extend particularly in the growth direction. In the case where the substrate is formed from the polycrystalline silicon ingot for the solar cell, there are many cases in which the ingot is sliced along a direction perpendicularly crossing the growth direction 207 of the crystal. However, in the case where the ingot is used as the base as in the present invention, when the ingot is sliced in parallel with the growth direction 207, an area per one crystal grain increases, and the adverse effect of the grain boundary is decreased. As a result, excellent characteristics of the solar cell are liable to be obtained. Since the cutting mark of the wire saw remains on the base surface which is left sliced, and stains are stuck onto the base surface, the base surface is etched. There are many cases in which the surface of the substrate for a solar cell is roughed by an alkali etching solution to form a texture structure. However, in case of the base, there is many cases in which the surface configuration of a silicon layer that grows on the substrate is different from the surface of the original base, and the roughing of the base surface has no significance and may cause abnormal growth. Rather, it is preferable that the surface of the base is planer-etched with a mixture solution of, for example, nitric acid: acetic acid: hydrofluoric acid=300:68:32 for several minutes so as to be smoothed after a solvent has been washed.

(Liquid-Phase Growth)

The high-purity polycrystalline silicon layer has to be formed on the low-purity base such as the above-mentioned metal-grade silicon. As the forming method, there are the gas-phase growth and the liquid-phase growth, but in the present specification, the liquid-phase growth that is advantageous from the viewpoint of the costs will be described.

In the case where a high-purity silicon wafer is used in the present invention, the formation of the polycrystalline silicon layer is not essential.

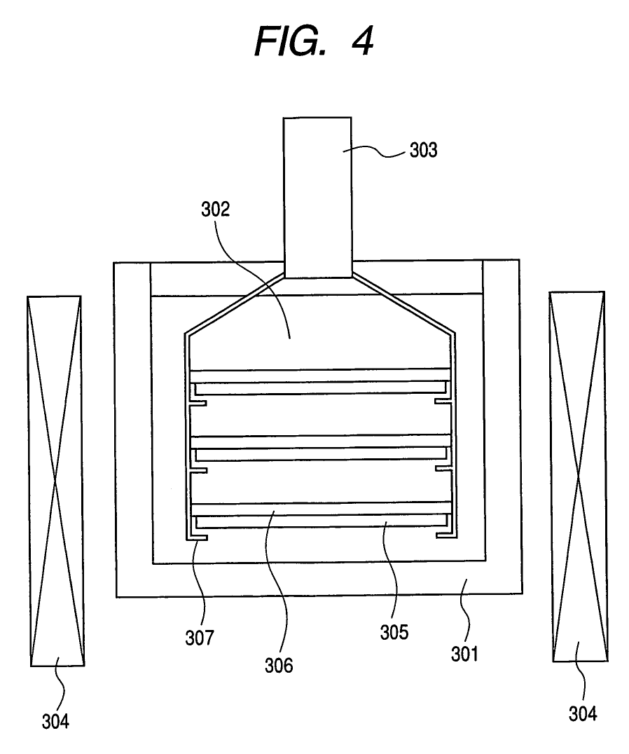

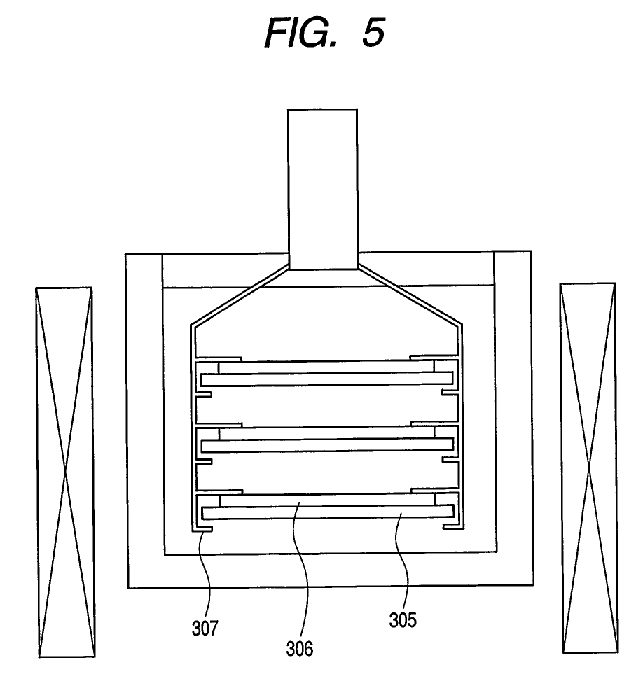

In the liquid-phase growth of silicon, a metal having a low melting point such as tin, indium, gallium, aluminum or copper is melted, and silicon is melted as metal in the melted metal. In particular, indium is preferable for the growth of silicon at a high speed because the melting point is appropriately low and easy to be dealt with, and it is difficult that indium is solid-soluble in silicon. Copper is preferable for the growth of silicon at a high rate because the solubility of copper to silicon is low. FIGS. 4 and 5 are cross-sectional views showing a liquid-phase apparatus preferred to an embodiment of the present invention. First, a crucible 301 is heated by a cylindrical heater 304 that surrounds the crucible 301 so that silicon is melted at a temperature of about 600 to 1200° C. in accordance with the kind of melt until silicon is saturated, to thereby form a melt 302. Metal-grade silicon that contains a large amount of impurities is improper as a silicon raw material to be melted. However, semiconductor-class (purity of about 10N to 11N) silicon is not required but solar cell class (purity of about 6N to 7N) silicon is acceptable for the silicon raw material to be melted. Then, a base 305 of polycrystalline silicon is immersed into the melt. In FIGS. 4 and 5, there are three bases, but tens or hundreds of bases can be treated for growth in accordance with the size of crucible 301. Before the liquid-phase growth starts, it is usual that after the temperature of the melt 302 is made higher than the saturation temperature of silicon so as to be unsaturated once, the base 305 is immersed into the melt 302, and a part of bases is melted into the melt so that the surfaces of the bases are adjusted to the melt. However, in the case where the base of metal-grade silicon is used, this process is not preferable because the impurities in the base are melted into the melt. When the base surface is appropriately etched, and a flow of reduction gas such as hydrogen is formed within a vessel that contains the bases and crucible, even if the bases are immersed into the melt after the temperature of the melt is made lower than the saturation temperature of silicon by about several to tens of ° C., the surface of the bases is adjusted to the melt, and there is no fear that the impurities are melt into the metal.

After the bases 305 have been immersed into the melt 302, the melt is cooled. When the melt has been cooled, silicon that cannot be melted any more is precipitated on the bases 305. Since the bases are composed of polycrystalline silicon, the precipitated silicon layer becomes polycrystal following the bases. There are many cases in which cooling is gradually conducted at a constant speed. This method is called “gradual cooling”. In the liquid-phase method, there is also a manner that is called “temperature difference method” in which the solid of a solute such as silicon and the bases are immersed into the melt together, the solute is maintained relatively at a higher temperature while the bases are maintained relatively at a lower temperature, the solute is eluted and diffused from the surface of the solute solid so that the solute is allowed to grow on the bases. The temperature difference method is preferably used in the growth of compound semiconductor that particularly requires the uniformity of the thickness direction of a grown film since the temperatures at the respective portions can be held constant from first to last. The temperature difference method is also preferably applied to the growth of silicon. The conductivity type and resistivity of the polycrystalline silicon layer are affected by the melt. Indium, gallium, aluminum or the like, per se are p-type dopant, and when the metal of this type is used for the melt, there are many cases in which the dopant is solid-solved into the silicon and becomes of p-type. In particular, indium is hardly solid-solved into the silicon, and the conductivity is readily controllable. Although, tin is slightly solid-solved into the silicon, tin is electrically inactive because of IV-group element, and the conductivity is controllable. In the case of using those melts, dopant such as B, aluminum, gallium, P or antimony is melted into the melt, and the liquid-phase growth is conducted, thereby being capable of freely controlling p-type or n-type.

In the case where the polycrystalline silicon layer is used as an active layer of the solar cell, the resistivity of the polycrystalline silicon layer is preferably about 0.1 to 10 Ωcm. If the resistivity is higher than the above upper limit, n⁺-p junction (or p⁺-n junction) between the polycrystalline silicon layer and the emitter layer is not sufficiently formed, and in particular, an open circuit voltage is dropped. Conversely, if the resistivity is lower than the above lower limit, a depletion layer is not sufficiently spread, and the recombination of carriers is also increased, and in particular, a short-circuit current is lowered. On the contrary, it is desirable that the base is of the same conductivity type and lower in the resistivity. With this, a p-p⁺ junction (n-n⁺ junction) is formed between the polycrystalline silicon layer and the base, a back surface field (BSF) effect is exhibited, the absorption of a long-wavelength light is strengthened to increase the short-circuit current, and the open circuit voltage is also improved. There are usually many cases in which the base is used as p+ (about 0.005 to 0.1 Ωcm) and the polycrystalline silicon layer is used as p (about 0.1 to 10 Ωcm), but even if the base is used as n+ (about 0.005 to 0.1 Ωcm) and the polycrystalline silicon layer is used as n (about 0.1 to 10 Ωcm), the same effects can be obtained.

Also, in the case where the polycrystalline silicon layer is used as the active layer of the solar cell, since the absorption of the incident light increases more as the polycrystalline silicon layer is thicker, it is desirable that the thickness is about 100 μm at minimum. However, a long period of time is required for the growth, and the amount of raw material silicon to be used increases, resulting in an increase in the costs. Therefore, there is proposed a method in which a texture structure is formed on the surface of the polycrystalline silicon layer by etching with an alkali solution or the like, and an optical path length of the incident light is extended to strength the absorption as generally applied in the crystalline silicon solar cell. However, this method is not preferable because the polycrystalline silicon layer that has grown after all the effort is lost.

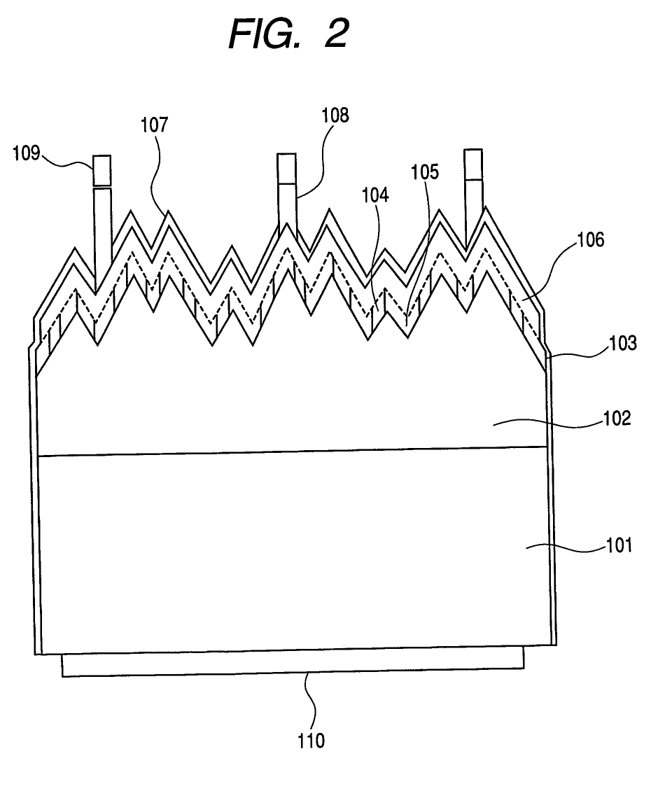

In the case where liquid-phase growth is conducted on the base which is made of crystalline silicon, there is a case in which a specific face orientation, in particular, a plane (facet face) having a (111) face preferentially appears on the surface of the polycrystalline silicon. Now, this will be described with reference to FIG. 2. Because the facet face is inclined with respect to the surface of the base 101, fine concaves and convexes having a pitch of several to tens of μm are formed on the surface of the polycrystalline silicon layer 102. In addition, in the polycrystalline silicon base, the orientations of the facet face are uniform within one crystal gain, but the orientations are different in the different crystal grains, and the orientations are at random as a whole. Even in the polycrystalline silicon layer 102 that is about 20 to 50 μm in the thickness, the same light absorption as that of a flat polycrystalline silicon layer that is 100 μm in the thickness is obtained due to the action of the fine concaves and convexes formed on the facet face. This method is advantageous from the viewpoints of the costs since all of the grown silicon are available and the etching process is not required as compared with the etching method.

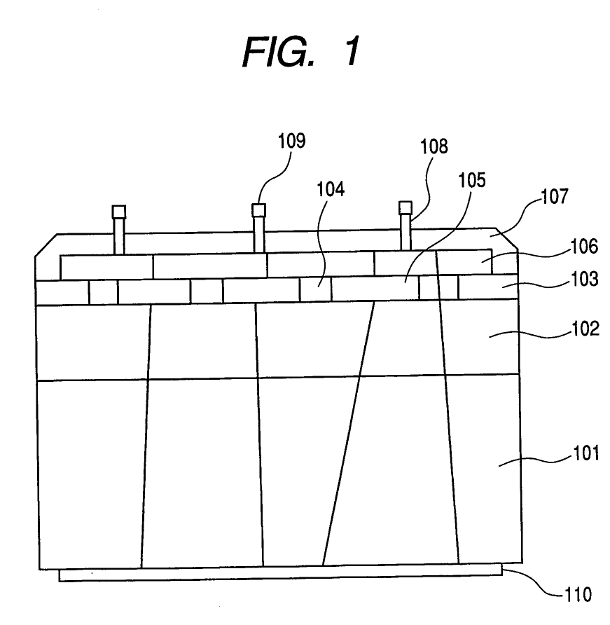

In the present invention, high-density dopant elements are contained in the base. Also, in particular, in the case where metal-grade silicon is used as a raw material, heavy-metal impurities that could not be removed are contained in the base. In the case of using the base of this type, the dopant elements or the heavy-metal impurities are diffused from the surface of the exposed base within a treating apparatus in a solar cell manufacturing process, which may adversely affect the characteristics of the completed solar cell. In particular, the adverse influence is liable to appear in a thermal diffusion step for forming the emitter layer (n⁺ type layer in the case where the polycrystalline silicon layer is of the p-type) of the surface, which is executed at a high temperature. Therefore, from the viewpoint of impurity diffusion prevention, it is desirable that the overall surface of the base is covered with a high-purity polycrystalline silicon layer when the liquid-phase growth is conducted. On the other hand, when the back surface of the base is covered with a polycrystalline silicon layer that is relatively high in resistance, an electric contact of the back surface is difficult to obtain. Therefore, as shown in FIGS. 1 and 2, it is possible that the liquid-phase growth is conducted in a given region of the back surface of the base 101 so as to expose the base surface, whereas the front surface and end surface of the base are perfectly covered with the polycrystalline silicon layer 102. In the case where the substrate thus formed passes through the solar cell manufacturing process, the diffusion of the impurities can be suppressed by a method in which a cover is put to the exposed portion or two substrates are put on each other back to back. Also, since the exposed portion is low in the resistance, the electric contact with the base can be readily taken.

The apparatus shown in FIGS. 4 and 5 are equipped with a mechanism for forming the exposed portion on only the back surface of the base in conducting the liquid-phase growth. In the apparatus shown in FIG. 4, each of the bases 305 is supported between a support plate 306 and a drop preventing claw 307. In this cross-sectional view, there are shown only two drop preventing claws 307, however in fact, the apparatus is of the structure in which each of the bases 305 is stably supported by at least three drop preventing claws. In this example, when each of the bases 305 is immersed in the melt 302, as shown in FIGS. 4 and 5, each of the bases 305 which are lower in the relative density than the melt 302 attaches to the support plate 306 due to a buoyancy, and the support plate 306 is so formed as to be slightly larger than each of the bases 305. As a result, the growth occurs on the front surface and end surface of the base, but the growth does not occur on the back surface of the base at all. Also, in the apparatus shown in FIG. 5, since the support plate 306 is so formed as to be slightly smaller than the base 305, the growth occurs on the periphery of the back surface of the base in addition to the front surface and end surface of the base. However, the growth does not occur and the exposed portion is formed in the portion that closely attaches to the support plate 307.

(Description of the Solar Cell Manufacturing Process)

FIG. 1 shows a cross-sectional structure of the solar cell in accordance with the present invention.

In FIG. 1, the polycrystalline silicon layer 102 is formed on the metal silicon base 101 through the liquid-phase method.

FIG. 2 shows a cross-sectional structure of the solar cell in accordance with the present invention. The surface of the polycrystalline silicon layer 102 is texture-shaped.

In general, the emitter layer 106 having the conductivity type opposite to that of the polycrystalline silicon layer 102 is formed on the polycrystalline silicon layer 102. However, taking the experimental results into consideration, a high-resistant silicon film containing H such as amorphous Si or microcrystalline Si is deposited in the thickness of 1 nm to 15 nm on the polycrystalline silicon layer 102, to thereby form the buffer layer 103. As a result, it has been found that the solar cell characteristics, in particular, the open circuit voltage is remarkably increased. This fact has been already disclosed in Japanese Patent Laid-Open Nos. H5-36611 and H5-48128. However, in all of those disclosures, a nondoped amorphous Si layer is used as the buffer layer, and a doped amorphous Si layer is used as the emitter layer 106. For that reason, because the conductivity of the emitter layer 106 is not sufficiently high, an ITO film is formed on the emitter layer 106 as the antireflection film having conductivity. Because the ITO film is electrically conductive, the ITO film absorbs the light, and the loss of the generated current appears. In the inventors' experiments, a current loss of about 5% appears in the ITO film that is 100 Ω in the sheet resistance. In the present invention, the structure of the buffer layer 103 has been studied under the condition that a transparent insulating film, in particular, an SiN film is used as the antireflection film 107, and the conductivity of the emitter layer is increased.

(Emitter Layer)

As a method of forming the emitter layer 106, there are a method of further growing a thin silicon layer doped with a dopant having a high density and a conductivity type opposite to that of the polycrystalline silicon layer on the surface of the polycrystalline silicon layer 102 grown in the liquid-phase, and a method of conducting the thermal diffusion or ion implantation of the dopant on the surface of the polycrystalline silicon layer to change the conductivity type of the uppermost surface having a thickness of thousands A if there arises no problem on the heat resistance of the buffer layer 103. As an n-type diffusion source, it is possible that a coating solution containing P is coated on the polycrystalline silicon layer, or a P₂O₅ layer formed on the surface of the polycrystalline silicon by oxidizing the polycrystalline silicon layer while an inertia gas containing POCl₃ is allowed to flow is utilized. As the p-type diffusion source, it is possible to utilize a B₂O₃ layer formed on the surface of the polycrystalline silicon by oxidizing the polycrystalline silicon layer while an inertia gas containing BBr₃ is allowed to flow. In order to obtain the emitter layer of this type due to the thermal diffusion, a temperature treatment at about 700 to 900° C. for several to tens of minutes is required, but it is difficult to apply this method from the viewpoint of the heat resistance of the buffer layer. Normally, the film forming method at 500° C. or lower is selected.

The depth of the junction of the emitter layer is about 1000 to 5000 Å, and the surface sheet resistance is about 10 to 500 Ω as a reference.

The electric conductivity of the amorphous Si is 10⁻⁴ S/cm even when the dopant is introduced at 10⁴ ppm as gas volume ratio, and 10⁻² S/cm even when ions of about 10²¹ cm⁻³ are implanted (Applied physical data handbook, Applied Physical Society, issued on Sep. 30, 1994).

In order to obtain the sheet resistance of 500 Ω or less by using the doped film of amorphous Si, the thickness of 0.2 cm is required even if the ion implantation is conducted, which is impractical.

A crystalline silicon film is used as the emitter layer. The conductivity depends on the amount of doping, the characteristics of the crystalline silicon film, in particular, grain diameter. In the experimental results of the film formed in the film forming method disclosed in Japanese Patent Application Laid-Open No. H8-250433 by the present inventors in advance, the B doped film which is the polycrystalline film with 200 nm in the crystal grain diameter has 6.7×10⁻² Ωcm in resistivity when the amount of B doping is 4.1×10¹⁹ cm⁻³ In the single-crystalline silicon, taking the fact that the resistivity is 5×10⁻³ Ωcm when the amount of B doping is 2×10¹⁹ cm⁻³ into consideration, it is considered that the crystal grain diameter is further increased, and the amount of B doping is set to 10²⁰ cm⁻³ order, to thereby obtain a desired conductivity for the thickness of about 150 nm.

The P doped polycrystalline film with 200 nm in the crystal grain diameter and 8×10⁻³ Ωcm in resistivity is obtained when the amount of P doping is 4×10²¹ cm⁻³. Accordingly, when the film thickness is 160 nm, the sheet resistance of the emitter layer can be set to 500 Ω or less.

(Buffer Layer)

An amorphous silicon layer that is not doped is introduced between the polycrystalline silicon layer 102 and the emitter layer 103, to thereby improve the open circuit voltage. The thickness of the amorphous silicon layer is made uniform, and it is necessary to sufficiently thin the amorphous silicon layer so as to prevent electric charges from being trapped and recombined during the process. Normally, the thickness of 1 nm to 5 nm is applied.

The crystalline emitter layer is formed on the amorphous silicon layer. There arise a problem. If an underlaying layer is not a crystalline substrate of silicon, it is difficult to directly form a crystal film with a large grain diameter immediately on the underlaying layer even in any one of the gas-phase method and the liquid-phase method. When the underlaying layer is amorphous, (1) an amorphous film is formed at the initial stage of the film formation, and after the incubation layer having a certain thickness has been formed, a crystal nucleus is formed and then grows into a polycrystalline film, or (2) microcrystalline grains formed in the gas phase is deposited on the underlaying layer. In the case of (1), the incubation layer is amorphous, and the thickness thereof is about 50 to 100 nm. That portion of the incubation hardly contributes to the conductivity of the emitter layer. On the other hand, from the viewpoints of the light absorption, the incubation layer as a light absorption layer higher than the crystalline silicon by one digit is stacked by 50 to 100 nm. A light that reaches the polycrystalline silicon layer 102 is reduced by the thickness. In the case of (2), the crystalline grain diameter is about 10 nm, and it is difficult to increase the conductivity even if the amount of doping increases. For that reason, in order to obtain the conductivity necessary for the emitter layer, the emitter layer must be thickened. For that reason, when the thickness of the emitter layer is extremely thickened, the light absorption by the emitter layer increases, and a light that reaches the polycrystalline silicon layer 102 reduced.

For that reason, there is applied a layer having a portion 104 in which a part of the buffer layer 103 becomes crystalline that reflects the crystallinity of the underlaying layer (a layer having an amorphous silicon phase and a microcrystalline silicon phase mixed together) as shown in FIG. 2. The rate of the crystalline portion 104 and the amorphous silicon portion 105 is determined depending on whether the emitter layer can be continuously grown on the buffer layer 103 with the crystalline portion 104 as the seed, or not. The film is formed under the growth condition of the emitter layer which approaches the balance condition in which the crystal growth and the etching exist together, thereby being capable of obtaining the conditions under which no film is formed on the amorphous silicon and the crystalline film extends laterally and becomes a continuous film. When the rate of the crystalline portion 104 is smaller, the film is formed even under the very severe balance conditions for a long period of time.

Accordingly, the rate of the crystalline portion and the amorphous portion is selected in a range of from 1:1 to 1:10.

There are various methods of forming a film having a crystalline portion and an amorphous portion mixed together, and a typical method is disclosed in Japanese Patent No. 2,965,094 by the present inventors. In this system, when infrared rays are periodically irradiated onto the polycrystalline silicon layer 102 so that the temperature becomes slightly higher, crystalline silicon is formed on only a portion where the infrared rays are irradiated and the temperature becomes higher, and amorphous silicon is formed on other portions.

(Formation of Antireflection Layer and Grid Electrode)

Since silicon has a high refractive index of about 3.4 and a high reflectivity with respect to air, it is necessary to form the appropriate antireflection layer 107 on the surface of silicon. As the antireflection layer, there is used a transparent film that is about 600 to 900 Å in the thickness and made of silicon nitride, titanium oxide, zinc oxide, zinc sulfide or the like which is about 1.8 to 2.3 in the refractive index and high in transparency. As the depositing method of the antireflection layer 107, the sputtering method, the thermal CVD method, the plasma CVD method or the like is generally used. In case of titanium oxide, a coating solution can be coated and fired to form the antireflection layer 107. There is a case in which the antireflection film has a function of preventing the recombination of carriers on the surface other than the mere optical function. From this viewpoint, the silicon nitride (SiN) film is particularly excellent, and since the silicon nitride is liable to obtain a large current, it is widely used.

A grid electrode 108 is formed on the surface of the emitter layer in order to take out a light current. Since the grid electrode 108 becomes a shadow with respect to the incident light, it is desirable that the width is as narrow as possible and the number of grid electrodes 108 is as small as possible. On the other hand, since a current is concentrated and flows in the grid electrodes, it is preferable that the resistance is lower. Also, it is necessary that each of the grid electrodes 108 has an excellent electric contact with the emitter layer 106. From this viewpoint, there are generally many cases in which a pattern of silver paste containing glass flit is printed and fired to the grid electrode 108. Since the antireflection film is generally high in the resistance, it is necessary that the grid electrode 108 comes in direct contact with the emitter layer 106. However, when the antireflection layer is formed on the grid electrode, there is an obstacle to a solder coat 109 on each of the grid electrodes which is printed to lower the resistance of the grid electrode. Therefore, after a region of the formed antireflection layer where each of the grid electrodes is to be formed is etched in advance to expose the emitter layer, each of the grid electrodes is formed. Alternatively, there is a method (fire through method) in which the pattern of the grid electrodes 108 is printed on the antireflection layer 107, and the antireflection layer is pierced by firing so that the grid electrodes 108 become in contact with the emitter layer 106. This method starts to be popularized since the etching of the antireflection layer and the positioning of the grid electrode pattern are unnecessary, and the productivity is high.

(Formation of the Back Surface Electrode and Isolation of the Emitter Layer)

In the general crystalline silicon solar cell, in order to conduct an electric contact on the back surface, in particular, in the case where the polycrystalline silicon layer is of the p-type, there are many cases in which aluminum paste is printed and fired to form back surface electrodes. The aluminum paste is widely applied because it is relatively inexpensive, aluminum is diffused into the substrate to form a back surface field (BSF) layer, and the use efficiency of the carriers generated in the vicinity of the back surface is improved to enhance the sensitivity of an incident light of a long wavelength. There are many cases in which aluminum past is contracted and bends the substrate when aluminum paste is fired, and particularly when the electrodes are formed on an overall back surface, the bending becomes remarkable. In this point, since the paste is low in the resistance in the present invention, it is not necessary to form the back surface electrode 110 on the entire surface at all as shown in FIG. 1, and divided pattern is available, and the divided pattern is readily used since the bending is small even if the aluminum paste is used.

As described above, the emitter layer 106 is formed on the surface of the polycrystalline silicon layer, and when the emitter layer comes in contact with the surface of the back surface electrode or the base, a light current is leaked and the solar cell characteristics are remarkably spoiled. In the present invention, because at least the front surface and the end surface 105 of the base are substantially covered with the polycrystalline silicon layer, there is no fear that the light current is leaked. Also, in the CVD process and the thermal diffusion process for formation of the emitter layer, when the back surfaces of the substrates are put on each other back to back and processed, it is particularly difficult that the emitter layer goes around the back surface, and a risk of the leakage is further low. However, in the case where a leakage between the emitter layer 106 and the back surface electrode 110 or the base 101 has particularly to be suppressed, the diffusion source of the dopant is printed by a pattern that avoids the peripheral portion of a substrate in the formation of the emitter layer, or the emitter layer on the peripheral portion of the substrate is etched and removed, or the front surface of the peripheral portion is scribed, to thereby conduct isolation. When the emitter layer on the peripheral portion of the substrate is etched or scribed, it is desirable to substantially remove the emitter layer in a given region. Conversely, when the removal is conducted until the surface of the base is exposed, leakage tends to occur unintentionally. Accordingly, it is necessary to control the depth of the layer to be removed. Also, in the case where a substantially-insulating antireflection film such as of silicon nitride is used, when isolation is conducted before the antireflection film is formed, the leakage preventing effect is further enhanced.

### EXAMPLES

Examples of the present invention will be described below.

### Example 1

An ingot was prepared with a mass of chemical grade metal class silicon produced in Brazil which is 1 to 25 mm as a raw material. After the mass of 1800 g was washed with acid, the mass was inserted into the apparatus shown in FIG. 3. A crucible 201 is made of carbon, and an inner surface of the crucible 201 is coated with SiN as a mold lubricant. The size of the inner surface is 80 mm in diameter×150 mm in depth. The inside of the apparatus was exhausted to 10 Pa, and thereafter Ar was allowed to flow into the apparatus at 1 atm. Three-stacked cylindrical side heaters 202 and the upper heater 203 were controlled, the crucible was heated to 1600° C., and all silicon within the crucible was melted for 10 hours and degassing was conducted, an output of the side heaters 202 was controlled to form a temperature slope of 50° C. from the upper toward the lower. In this state, a stand 204 that holds the crucible was extremely slowly pulled down, and silicon was solidified from the bottom surface of the crucible 201. The solidification was completed in 10 hours, the outputs of both the heaters were gradually lowered, and silicon was cooled for 10 hours. Grain boundaries extended vertically in the solidified ingot. Reference numeral 205 denotes solidified Si portion, and reference numeral 206 is a melted Si portion. The temperature was controlled so that crystal grows in a direction 207 in a state where solid-liquid interface is kept horizontally. The ingot was sliced into a wafer by a band saw, the surface of the wafer was etched, and the resistivity was measured. As a result, the resistivity of the n-type was 10 Ωcm. Then, the ingot was again solidified under the same conditions except that 900 mg of B₂O₃ was added to the metal class silicon raw material. B₂O₃ was dissolved in water and diluted, and adjusted so that a given amount of B₂O₃ was added to the silicon raw material. The conductivity type of a sample to which B₂O₃ was added was p-type, and the resistivity was 0.015 Ω/cm.

As a result of analyzing the impurities through the ICP method, the density of iron and chromium was 1 ppm or lower except for a portion that extends 2.5 cm from the surface of the ingot.

The metal-grade silicon on the wafer thus obtained was used as the base as follows. The surface of the base was subjected to planer etching with a mixed solution of nitric acid:acetic acid:hydrofluoric acid=300:68:32 for two minutes to remove the cutting mark of the wire saw which remains on the base, thus obtaining a glossy surface.

A polycrystalline silicon layer was allowed to grow by a liquid-phase apparatus shown in FIG. 4. Indium was put into the crucible 301, heated at 930° C. and dissolved while that temperature is held. Then, a p-type solar cell class polycrystalline silicon plate that was 3 mm in the thickness was set instead of the base, and immersed into the dissolved indium. Silicon was dissolved into indium and saturated, and the melt 302 was adjusted. The polycrystalline silicon plate was pulled up once, and the base that had been prepared in advance was mounted instead. After the atmosphere around the crucible was replaced by hydrogen, the melt 302 was cooled by 7° C. When the temperature of the melt became 923° C., the base was immersed into the melt to allow to grow for one hour while the state of 930° C. is kept, and thereafter the base was pulled up from the melt. After pulling up, since a small amount of indium stuck onto the base was found, the overall base was immersed into hydrochloric acid for one hour to remove indium. After taking out the base 302, the polycrystalline silicon layer 102 with a thickness of about 30 μm grew on the base 101. The growth surface was flat. Hereinafter, the structure of the substrate and the solar cell is described with reference to FIG. 1. Also, as a result of measuring the resistivity of the polycrystalline silicon layer grown grew on the n-type base through the four-probes measurement, the resistivity was 0.8 to 1.2 Ωcm. In this example, the reason why the n-type base was used is that a depletion layer is formed between the base and the p-type polycrystalline silicon layer 102, the polycrystalline silicon layer is electrically isolated from the base, and the resistivity is measured with a high precision. Also, the polycrystalline silicon layer completely covered not only the front surface of the base but also the end surface of the base, but the growth was not found on the back surface. Thus, the solar cell polycrystalline silicon substrate was completed.

Subsequently, the solar cell was fabricated by using the above polycrystalline silicon substrate.

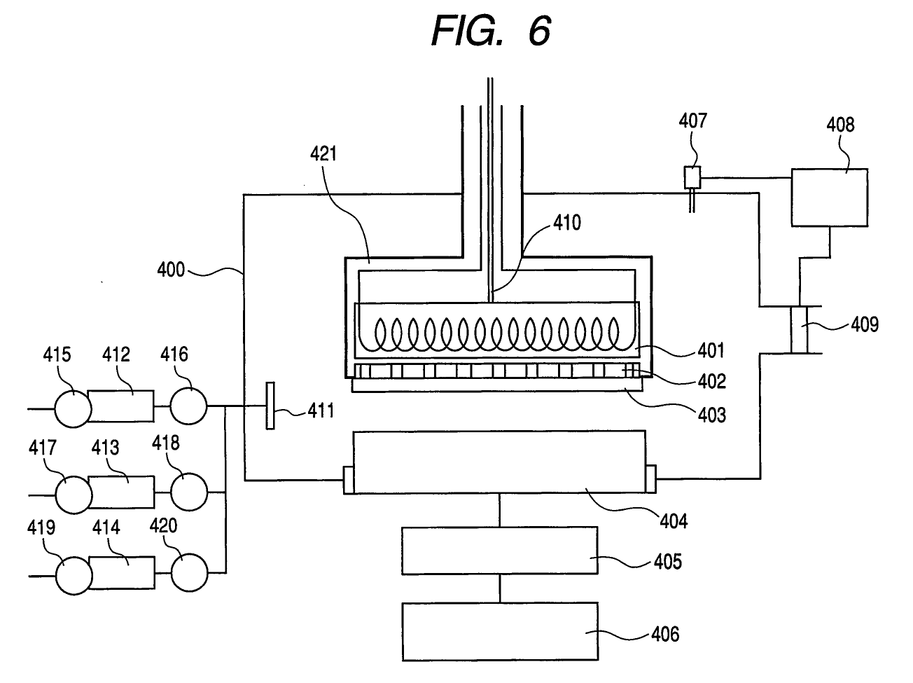

The substrate was installed into a plasma CVD apparatus shown in FIG. 6, a translucent mask 402 is equipped between a substrate 403 and an infrared lamp 401 for heating the substrate, and the temperature of the substrate was 300° C. but was adjusted so as to periodically provide a region of 350° C. in the form of a lattice. The periodic interval was set to about 5 mm. Among the cyclic intervals, about 2 mm was set as a high-temperature region. After the inside of a chamber 400 was sufficiently exhausted, 20 sccm of SiF₄ gas and 35 sccm of H₂ gas were introduced into the chamber 400. A sequence that SiF₄ gas was introduced for 10 seconds and stopped for 30 seconds is repeated. H₂ was constantly introduced. After the internal pressure of the chamber was set to 13 Pa, 100 W of a VHF power was applied to form a film. Those conditions are one example, and largely different depending on the configuration of the chamber. What is important is conducting deposition at different temperatures under the conditions an amorphous silicon film and an epitaxial layer that reflects the information of an underlaying substrate can be formed. In this way, a buffer layer with 10 nm in thickness was formed. In the apparatus shown in FIG. 4, reference numeral 400 denotes a chamber, reference numeral 401 denotes an infrared lamp for heating the substrate, reference numeral 402 denotes a translucent mask, reference numeral 403 denotes a substrate, reference numeral 404 denotes a cathode electrode, reference numeral 405 denotes a matching box, reference numeral 406 denotes a VHF power supply, reference numeral 407 denotes a pressure sensor, reference numeral 408 denotes a pressure gauge and a valve open/close control device, reference numeral 409 denotes an automatic open/close valve, reference numeral 410 denotes a thermo couple, reference numeral 411 denotes a gas jet outlet, reference numerals 412, 413 and 414 denote gas flow rate control devices, respectively, reference numerals 415 to 420 denote valves, respectively, and reference numeral 421 denotes a substrate holder.

Then, the sample was moved to another chamber of the same configuration, and the temperature of the substrate was set to 350° C. After the inside of the chamber was sufficiently exhausted, 20 sccm of SiF₄ gas, 35 sccm of H₂ gas and 10 sccm of PH₃ (PH₃/H=1%) gas were introduced into the chamber. After the internal pressure of chamber was set to 13 Pa, 100 W of the VHF power supply was applied to form the film. In the gas introduction sequence, (1) SiF₄ and H₂ introduction and PH₃ stop for 10 seconds, (2) PH₃ and H₂ introduction and SiF₄ stop for 10 seconds, and (3) only H₂ introduction for 40 seconds were repeated. Those conditions are one example and largely different depending on the configuration of the chamber, etc. In this example, there are two important points. That is, (1) a flat polycrystalline film is formed on a buffer layer with a crystal phase of the buffer layer as the seeds. (2) The sheet resistance of the polycrystalline film can be set to 500 Ω or lower with the thickness of 150 nm. Also, in order to prevent a current from being leaked at the end surface, the peripheral portion was masked for isolation at the time of forming the film.

Then, in order to form a silicon nitride film as the antireflection film 107, the substrate was put into another plasma CVD chamber. The substrate was mounted on a susceptor heated at a temperature of 300° C. An RF voltage was applied to a cathode that faced the substrate while flowing silane gas, ammonium gas and nitride gas mixed together and a silicon nitride film was deposited on the surface. The deposited silicon nitride film 107 was so deposited as to also cover the end surface 106. The reflection spectrum of the surface was measured by a spectroreflectometer with an integrating sphere, and the thickness of the silicon nitride film and the refractive index were adjusted so that the reflective index is minimum at about 620 nm, and the reflective index becomes 10% or lower in a range of the wavelength 450 nm to 1000 nm. The film forming conditions are not particularly limited. What is important is the reflection spectrum.

Then, after an aluminum paste was printed as a back surface electrode 110 by using a screen printing apparatus and dried, a pattern of silver paste was printed on the surface as the grid electrode 108 and then dried. This was put into an infrared ray belt firing furnace. A zone of 450° C. and a zone of 800° C. were provided in the firing furnace, two substrates were arranged in each of those zones, a belt was driven at a speed of 100 mm/minute while a large amount of air was blown, and those substrates passed through the respective zones to fire the pastes. Silver grains pierced through the antireflection film 107 and reached the emitter layer 106 to make an excellent electric contact with the emitter layer. On the other hand, the aluminum paste made an excellent electric contact with the back surface of the base by melting aluminum.

Finally, in order to form a solder coating layer 109, the respective two substrates were accommodated into cassettes. The cassettes were first immersed in a flax tank and dried by a hot air, and immersed in a solder flow tank for a given period of time. After that, the cassette was pulled up, and dried after washing it with a hot water. The solder was coated on only the grid of the silver paste.

In this way, the solar cell shown in FIG. 1 was fabricated.

### Example 2

The buffer layer was formed in the following manner different from that of the buffer layer formed in Example 1.

After an amorphous silicon film was formed on a substrate, an excimer laser was periodically irradiated onto the amorphous silicon film, and an irradiated portion was crystallized. In this example, the substrate remains cooled, for example, was put on a water-cooled holder, so that a non-irradiated portion was not crystallized.

### Example 3

The buffer layer was formed in the following manner different from that of the buffer layer formed in Example 1.

A laser power in Example 2 was intensified, the amorphous silicon of the irradiated portion was gasified, and a hole from which polycrystalline silicon formed through liquid phase on the substrate was exposed was formed in the amorphous silicon.

### Example 4

The growth conditions of polycrystalline silicon in the liquid phase apparatus in Example 1 were set as follows. That is, indium was put into a crucible 301, heated at 950° C. and melted while this temperature was maintained. Then, a p-type solar cell class polycrystalline silicon plate with 3 mm in thickness was set instead of the base and immersed in the melted indium, and silicon was dissolved in indium, and saturated to adjust the melt 302. The polycrystalline silicon plate was pulled up once, and a base prepared in advance was mounted instead. After the atmosphere around the crucible was replaced by hydrogen, the melt 302 was cooled at a rate of 1° C. per minute. When the temperature of the melt became 945° C., the base was immersed into the melt and then pulled up after growth continued for one hour. After pulling up, since a small amount of indium stuck onto the base was found, the overall base was immersed into hydrochloric acid for one hour to remove indium. After taking out the base 302, the polycrystalline silicon layer 102 with about 30 μm in thickness grew on the base 101. Hereinafter, the structure of the substrate and the solar cell is described with reference to FIG. 2. Also, as a result of observing the surface of the substrate by a metallurgical microscope, fine concaves and convexes having a pitch of 5 to 10 μm were observed. In addition, as a result that the cross section of the polycrystalline silicon layer was observed, the concaves/convexes were structured by terraces that are directed toward a given direction in each of the crystal grains. The terraces were judged to be facet faces 103 that accompany the crystal growth. Thereafter, the same procedures as those in Example 1 was proceeded to fabricate the solar cell with the structure shown in FIG. 2.

According to the present invention, in the silicon substrate for a solar cell, formed by allowing a high-purity polycrystalline silicon layer to grow on a surface of a base sliced from a polycrystalline silicon ingot which is obtained by melting metal-grade silicon and solidifying the silicon in one direction, 2×10¹⁸ cm³ to 5×10¹⁹ cm⁻³ of B or 1×10¹⁹ cm⁻³ to 1×10²¹ cm⁻³ of Al is added to the metal class silicon, and then melted and solidified in one direction to form a polycrystalline silicon ingot. With the use of this polycrystalline silicon substrate for a solar cell, a polycrystalline silicon substrate for a solar cell which is equivalent to the conventional substrate is obtained with 1/10 of the used amount of the conventional high-purity silicon raw material. For that reason, the costs of the solar cell are reduced as compared with the conventional polycrystalline silicon substrate, and production restrictions are small. Moreover, the substrate according to the present invention is equivalent in the configuration to the conventional polycrystalline silicon substrate, and is allowed to flow in a production line of the conventional solar cell with a slight modification that does not influence the costs. Therefore, additional investments in the production line of the solar cell are not required.

1. A solar cell comprising a silicon substrate for a solar cell, formed by allowing a high-purity polycrystalline silicon layer to grow on a surface of a base sliced from a polycrystalline silicon ingot which is obtained by melting metal-grade silicon and solidifying the silicon in one direction, wherein a layer having a non-doped amorphous silicon phase and a microcrystalline silicon phase mixed together is stacked on the high-purity polycrystalline silicon layer.

2. A solar cell according to claim 1, wherein a thickness of the layer having the non-doped amorphous silicon phase and the microcrystalline silicon phase mixed together ranges from 1 nm to 15 nm.

3. A solar cell according to claim 1 or 2, wherein a ratio of the amorphous silicon phase and the microcrystalline silicon phase in the layer having the non-doped amorphous silicon phase and the microcrystalline silicon phase mixed together ranges from 1:1 to 10:1.

4. A solar cell comprising a crystalline silicon substrate or a crystalline silicon layer, a layer having an amorphous silicon phase and a microcrystalline silicon phase mixed together, and a polycrystalline silicon layer grown with the microcrystalline silicon phase as a seed, which are stacked in mentioned order.
